(19) United States
(12) Patent Application Publication
(10) Pub. No.: US 2015/0240357 A1
(43) Pub. Date: Aug. 27, 2015

(54) SUBSTRATE PROCESSING APPARATUS USING ROTATABLE TABLE

(71) Applicant: TOKYO ELECTRON LIMITED, Tokyo (JP)

(72) Inventors: Mitsuhiro TACHIBANA, Nirasaki City (JP); Yuji TAKABATAKE, Oshu-shi (JP); Manabu HONMA, Oshu-shi (JP)

(21) Appl. No.: 14/628,661

(22) Filed: Feb. 23, 2015

(30) Foreign Application Priority Data
Feb. 25, 2014 (JP) 2014-034336

(51) Int. Cl. C23C 16/458; C23C 16/455

(52) U.S. Cl. CPC C23C 16/4584; C23C 16/45544; C23C 16/4586

(57) ABSTRACT

A substrate processing apparatus performing substrate processing by supplying a process gas to a circular substrate loaded on a rotatable table in a vacuum container while rotating the substrate, including: a recess formed at one side of the rotatable table to receive the substrate; a heater heating the rotatable table to heat the substrate to 600 degrees or more for processing; and six support pins disposed on a bottom surface of the recess such that the support pins are respectively placed at vertices of a regular hexagon, support the substrate at locations separated a distance of two-thirds (2/3) of a radius of the substrate from a center of the substrate, and support the substrate in a state of being raised from the bottom surface of the recess.

### CROSS-REFERENCE TO RELATED APPLICATION

This application claims the benefit of priority from Japanese Patent Application No. 2014-034336, filed on Feb. 25, 2014, in the Japan Patent Office, the disclosure of which is incorporated herein in its entirety by reference.

### TECHNICAL FIELD

The present disclosure relates to a substrate processing apparatus that performs substrate processing by supplying gas to a substrate loaded on a rotatable table in a vacuum container.

### BACKGROUND

For formation of a thin film such as a silicon oxide (SiO₂) layer on a substrate such as a semiconductor wafer (hereinafter, referred to as a “wafer”), a film formation apparatus for atomic layer deposition (ALD) is known in the art. In the film formation apparatus, a horizontal rotatable table is placed within a processing container evacuated to generate a vacuum atmosphere and is formed with a plurality of recesses along the circumference thereof to receive wafers. The wafers are sequentially received in and removed from the recesses through intermittent rotation of the rotatable table and operation of lift pins, which move up and down over bottom surfaces of the recesses.

After the rotatable table receives the wafers, gas is supplied from a plurality of gas nozzles disposed to face the rotatable table during rotation of the rotatable table. As the gas nozzles, a nozzle for supplying a process gas to generate a process atmosphere in order to form, for example, a silicon oxide layer, and a nozzle for supplying an isolation gas for separating the respective process atmospheres above the rotatable table are alternately arranged.

In order to improve film quality of wafers, it is proposed to increase the temperature of the wafer to a typical annealing temperature of 600 degrees C. or more during processing by the film formation apparatus. In this case, after the wafers are delivered to the recesses, the temperature of the rotatable table is increased to, for example, 600 degrees C. or more in order to start rapid film formation processing.

However, it is confirmed that the wafer undergoes bending when loaded on the bottom surface of the recess having a high temperature. The inventors of the present invention believe that such bending occurs due to the high quantity of heat flowing into the wafer with respect to the entire area of the wafer for a predetermined period of time after the wafer is loaded on the bottom surface of the recess, that is, due to a high heat flow rate of heat flowing into the wafer. That is, the inventors believe that the bending occurs because each part of the surface of the wafer has a temperature increase that greatly differs from the other parts. As the temperature of the wafer is further increased after the occurrence of bending, the bottom surface of the recess and the wafer are in a state of thermal equilibrium, so that in-plane heat conduction of the wafer relieves an in-plane temperature gradient (temperature difference) in the wafer, thereby relieving bending of the wafer.

In a bent state of the wafer as described above, the wafer can bulge above an upper end of a sidewall of the recess. When the rotatable table is rotated in this state, there is a possibility of interference between the corresponding wafer and the ceiling of the vacuum container, which constitutes an isolation region described below. In addition, if the rotatable table is rotated when the periphery of the wafer bulges above the sidewall of the recess due to its bending, the periphery of the wafer is put on the sidewall by the centrifugal force such that the wafer can be separated from the recess. Further, when the wafer is bent such that a lower surface of the wafer bulges downwards to reduce a contact area between the lower surface of the wafer and the bottom surface of the recess, there is a possibility of displacement of the wafer within the recess in a rotational direction due to centrifugal force and inertial force occurring upon rotation of the rotatable table. Such bending of the wafer is caused not only by a high heat flow rate into the wafer, but also by characteristics of heaters, which heat the rotatable table. That is, temperature distribution is created on the bottom surface of the recess upon delivery of the wafer to provide the in-pane temperature gradient in the wafer, thereby causing bending of the wafer.

Under such circumstances, since rotation of the rotatable table needs to stop until bending of the wafer is relieved after delivery of the wafer to one recess, it is difficult to achieve improvement in productivity of the film formation apparatus. In the past, formation of protrusions on the bottom surface of the recess to support the substrate has been known, but there was no consideration as to problems in the case where the wafer is processed at high temperature, as described above.

### SUMMARY

Some embodiments of the present disclosure provide a substrate processing apparatus that can prevent a substrate from bending in a rotatable table during substrate processing by supplying gas to the substrate in a vacuum atmosphere, thereby improving throughput of the apparatus.

According to one embodiment of the present disclosure, there is provided a substrate processing apparatus performing substrate processing by supplying a process gas to a circular substrate loaded on a rotatable table in a vacuum container while rotating the substrate. The apparatus includes a recess formed at one side of the rotatable table to receive the substrate; a heater heating the rotatable table to heat the substrate to 600 degrees C. or more for processing; and six support pins disposed on a bottom surface of the recess such that the support pins are respectively placed at vertices of a regular hexagon, support the substrate at locations separated by a distance of two-thirds (⅔) of a radius of the substrate from a center of the substrate, and support the substrate in a state of being raised from the bottom surface of the recess.

According to another embodiment of the present disclosure, there is provided a substrate processing apparatus performing substrate processing by supplying a process gas to a substrate loaded on a rotatable table in a vacuum container while rotating the substrate. The apparatus includes a recess formed at one side of the rotatable table to receive the substrate; a heater heating the rotatable table to heat the substrate to 600 degrees C. or more for processing; a bottom surface forming portion constituting a bottom surface of the recess on which the substrate is loaded in the rotatable table; and a table body constituting the outside of the bottom surface in the rotatable table, wherein the bottom surface forming portion is mainly formed of a material having higher thermal conductivity than the table body to suppress an in-plane temperature difference in the substrate by improving temperature uniformity within the bottom surface.

According to another embodiment of the present disclosure, there is provided a substrate processing apparatus performing substrate processing by supplying a process gas to a circular substrate loaded on a rotatable table in a vacuum container while rotating the substrate. The apparatus includes a recess formed at one side of the rotatable table to receive the substrate; a heater heating the rotatable table to heat the substrate to 600 degrees C. or more for processing; and a plurality of support pins disposed on a bottom surface of the recess to support the substrate in a state that the substrate is raised from the bottom surface of the recess, wherein a contact area ratio of the support pins with respect to an overall surface area of one surface of the substrate supported by the support pins ranges from 8% to 12% to reduce a rate of heat transfer from the bottom surface of the recess to the substrate.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional-view of a film formation apparatus according to a first exemplary embodiment of the present disclosure.

FIG. 2 is a perspective view schematically showing an internal configuration of the film formation apparatus.

FIG. 3 is a transverse sectional-view of the film formation apparatus.

FIG. 4 is a plan view of a rotatable table of the film formation apparatus.

FIG. 5 is a longitudinal sectional-view of the rotatable table.

FIG. 6 is a longitudinal sectional-view of a rotatable table according to a comparative embodiment.

FIG. 7 is a longitudinal sectional-view of the rotatable table according to the comparative embodiment.

FIG. 8 is a longitudinal sectional-view of the rotatable table.

FIG. 9 is a longitudinal sectional-view of the rotatable table.

FIG. 10 is a longitudinal sectional-view of the rotatable table.

FIG. 11 is a longitudinal sectional-view of a vacuum container of the film formation apparatus in a circumferential direction.

FIG. 12 is a longitudinal sectional-view of the vacuum container of the film formation apparatus in a circumferential direction.

FIG. 13 is a longitudinal sectional-view of the vacuum container of the film formation apparatus in a circumferential direction.

FIG. 14 is a view illustrating a flow of gas during film formation processing.

FIG. 15 is a longitudinal sectional-view of the rotatable table.

FIG. 16 is a longitudinal sectional-view of the rotatable table.

FIG. 17 is a longitudinal sectional-view of the rotatable table according to the comparative embodiment.

FIG. 18 is a longitudinal sectional-view of the rotatable table according to the comparative embodiment.

FIG. 19 is a plan view of a recess of a rotatable table according to a second embodiment of the present disclosure.

FIG. 20 is a longitudinal sectional-view of the rotatable table.

FIG. 21 is a longitudinal sectional-view of the rotatable table.

FIG. 22 is a longitudinal sectional-view of modification of the rotatable table according to the second embodiment of the present disclosure.

FIG. 23 is a plan view of a recess of a rotatable table according to a third embodiment of the present disclosure.

FIG. 24 is a longitudinal sectional-view of the rotatable table.

FIG. 25 is a longitudinal sectional-view of the rotatable table.

FIG. 26 is a plan view of modification of the recess of the rotatable table according to the third embodiment of the present disclosure.

FIG. 27 is a plan view of a first modification of the recess according to the first embodiment of the present disclosure.

FIG. 28 is a plan view of a second modification of the recess according to the first embodiment of the present disclosure.

FIG. 29 is a plan view of a third modification of the recess according to the first embodiment of the present disclosure.

FIG. 30 is a plan view of a fourth modification of the recess according to the first embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

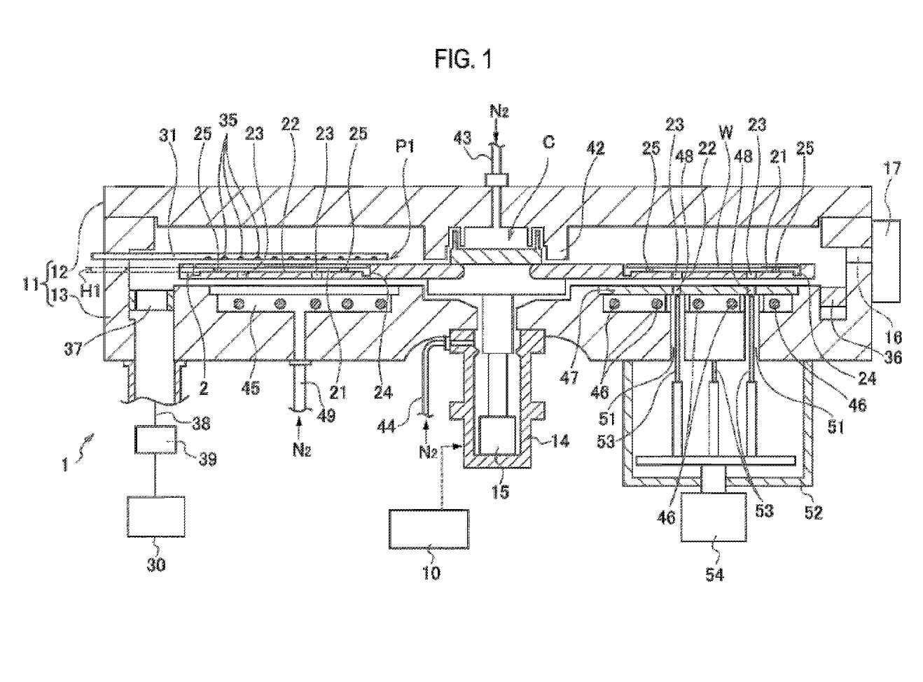

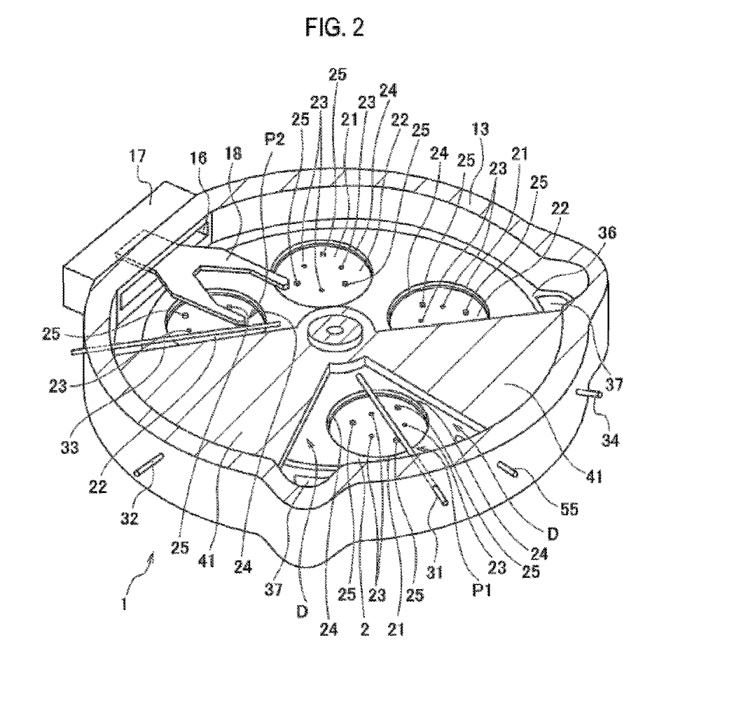

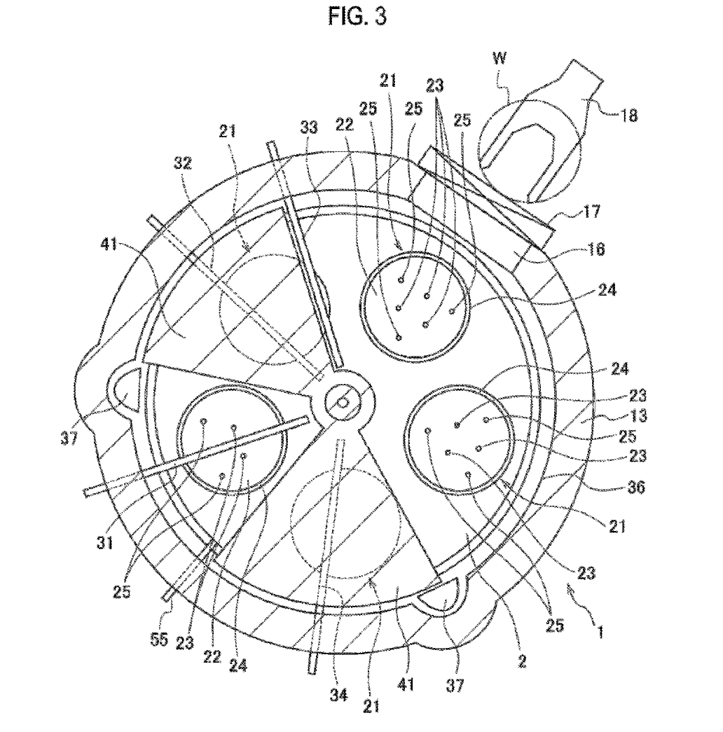

Referring to FIGS. 1 to 3, as one embodiment of a substrate processing apparatus according to the present disclosure, a film formation apparatus 1 for performing ALD onto a wafer W, which is, for example, a silicon substrate, will be described. FIG. 1 is a longitudinal sectional-view of the film formation apparatus 1. FIG. 2 is a schematic perspective view illustrating an internal configuration of the film formation apparatus 1. FIG. 3 is a transverse sectional-view of the film formation apparatus 1. The film formation apparatus 1 includes a substantially circular flat vacuum container (processing container) 11 and a disk-shaped horizontal rotatable table 2 disposed within the vacuum container 11. The vacuum container 11 is composed of a ceiling plate 12 and a container body 13 constituting a sidewall and a bottom surface of the vacuum container 11. In FIG. 1, reference numeral 14 indicates a cover that blocks a central portion of a lower side of the container body 13.

The rotatable table 2 is formed of quartz and is connected to a rotation driving mechanism 15 to be rotated about a central axis thereof in a circumferential direction by the rotation driving mechanism 15. Five circular recesses 21 are formed at a surface side (one side) of the rotatable table 2 along its rotational direction. A wafer W is received in the recess 21. The wafer W has a circular shape with a diameter of 300 mm. Each of the recesses 21 has a slightly greater diameter than the wafer W and includes a sidewall corresponding to an outer shape of the wafer W. Rotation of the rotatable table 2 causes the wafer W within the recess 21 to rotate about the central axis of the rotatable table 2. The configuration of the recess 21 will be described in detail below.

A transport opening 16 for wafers W is formed at a sidewall of the vacuum container 11, and is configured to be opened or closed by a gate valve 17. A wafer transport mechanism 18 placed outside the film formation apparatus 1 may enter the vacuum container 11 through the transport opening 16. The wafer transport mechanism 18 delivers the wafer W to the recess 21 facing the transport opening 16 or receives the wafer W from the recess 21.

A first reaction gas nozzle 31, an isolation gas nozzle 32, a second reaction gas nozzle 33 and an isolation gas nozzle 34 are arranged in order above the rotational table 2 in the circumferential direction and each of them has a bar shape extending from an outer periphery of the rotatable table 2 towards the center thereof. Each of the gas nozzles 31 to 34 is provided at a lower side thereof with an opening 35 through which gas is supplied in a radial direction of the rotatable table 2. The first reaction gas nozzle 31 ejects bis-tert-butylaminosilane (BTBAS) gas and the second reaction gas nozzle 33 ejects ozone (O₃) gas. The isolation gas nozzles 32, 34 eject nitrogen (N₂) gas.

The ceiling plate 12 of the vacuum container 11 is provided with two fan-shaped bump features 41, which protrude downwards and are separated a predetermined distance from each other in the circumferential direction. Each of the isolation gas nozzles 32, 34 is deeply fitted into the corresponding bump feature 41 and is disposed to isolate the corresponding bump feature 41 from the other bump feature in the circumferential direction. The first reaction gas nozzle 31 and the second reaction gas nozzle 33 are spaced apart from the bump features 41, respectively. A gas supply region below the first reaction gas nozzle 31 is referred to as a first processing region P1 and a gas supply region below the second reaction gas nozzle 33 is referred to as a second processing region P2. A lower area of the bump features 41, 41 is composed of isolation regions D, D, to which nitrogen (N₂) gas is supplied from the isolation gas nozzles 32, 34.

On the bottom surface of the vacuum container 11, a ring plate 36 is placed outside the rotatable table 2 in the radial direction thereof. The ring plate 36 is formed with exhaust ports 37, 37 arranged at certain intervals in the rotational direction of the rotatable table 2. Each of the exhaust ports 37 is connected to one end of each exhaust pipe 38, and the other ends of the exhaust pipes 38 are combined and connected to an exhaust mechanism 30 including a vacuum pump, with an exhaust adjustment mechanism 39 interposed therebetween. The exhaust adjustment mechanism 39 adjusts an exhaust amount of each of the exhaust ports 37, thereby adjusting pressure in the vacuum container 11.

The film formation apparatus 1 is configured such that N₂ gas is supplied to a space above a central region C of the rotatable table 2 through a gas supply pipe 43. In this case, N₂ gas acts as a purge gas and flows outwards in the radial direction of the rotatable table 2 through a downward flow passage of a ring-shaped protrusion 42 that protrudes downwards in a ring shape from a central portion of the ceiling plate 12. A lower surface of the ring-shaped protrusion 42 is successively connected to lower surfaces of the bump features 41 defining the isolation regions D.

In FIG. 1, reference numeral 44 indicates a gas supply pipe for supplying N₂ gas acting as a purge gas towards a lower side of the rotatable table 2 during film formation processing. In addition, the vacuum container 11 has a ring-shaped heater receiving space 45 defined on the bottom thereof and is provided with a plurality of heaters 46 arranged in a concentric circle shape within the heater receiving space 45 in the rotational direction of the rotatable table 2 in plan view. In FIG. 1, reference numeral 47 indicates a plate that blocks an upper side of the heater receiving space 45 and is formed with through-holes 48, through which lift pins 53 described below pass. The plate 47 is heated by radiant heat from the heaters 46 and the rotatable table 2 is also heated by radiant heat from the plate 47, so that the wafer W is heated. In FIG. 1, reference numeral 49 indicates a gas supply pipe for supplying N₂ gas as a purge gas to the heater receiving space 45 during film formation processing.

The container body 13 of the vacuum container 11 is formed with three through-holes 51, which are formed in a vertical direction through a bottom of the container body 13 so as to overlap the through-holes 48 of the plate 47 (for convenience, only two through-holes are shown in FIG. 1). The container body 13 is provided at a lower side thereof with a box-shaped member 52, which has a bottom and blocks the through-holes 51 from the lower side of the container body 13, and three lift pins 53 are formed in the box-shaped member 52. Each of the lift pins 53 is disposed to enter the corresponding through-hole 51 and is connected to a drive mechanism 54 installed outside the box-shaped member 52 and is configured to be lifted and lowered by the drive mechanism 54.

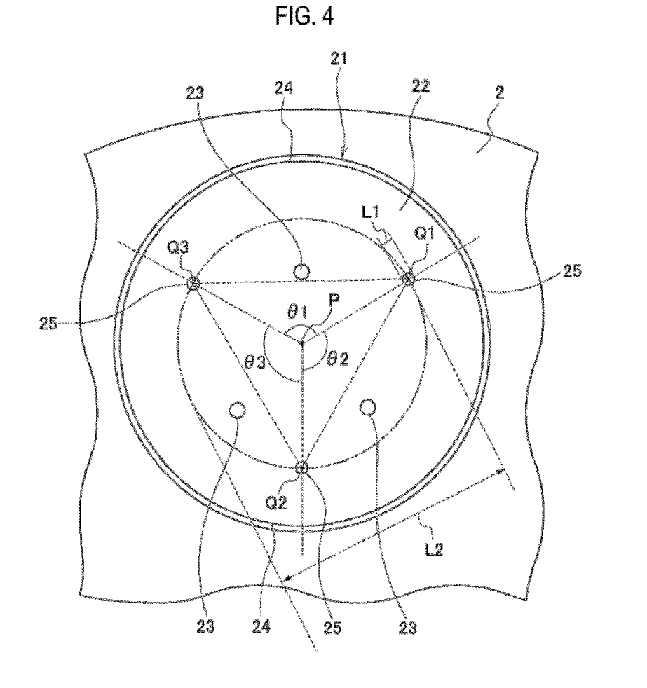

Next, the configuration of the recess 21 of the rotatable table 2 will be described with reference to FIG. 4, which is a plan view of the recess 21. The recess 21 has three through-holes 23 formed at a bottom surface 22 thereof such that the lift pins 53 can be lifted upwards on the rotatable table 2 through the through-holes 23. The bottom surface 22 of the recess 21 is formed with a ring-shaped groove 24 along a periphery thereof. The groove 24 serves to prevent friction between a circumference end of the wafer W and the bottom surface 22 of the recess 21 when the wafer W is bent such that the circumference end of the wafer W is placed below the center of the wafer. It should be noted that the groove 24 may be omitted from the recess 21.

The recess 21 is provided with three support pins 25 on the bottom surface 22 thereof. The support pins 25 have a cylindrical shape and are formed of, for example, quartz. In FIG. 4, each of the support pins 25 has a diameter L1 of, for example, 10 mm. In addition, in FIG. 1, the support pin 25 has a height H1 of, for example, 0.6 mm. In FIG. 4, a point P indicates a center of the bottom surface 22 and the wafer is delivered above the bottom surface 22 such that the center of the wafer W overlaps the point P. In this figure, reference numerals Q1, Q2 and Q3 indicate central points of upper surfaces of the support pins 25, respectively. These points Q1, Q2, Q3 are placed in this order on a circumference of a circle (indicated by a dash-dot-dot line in FIG. 4) having a center at the point P, and the circle indicated by the dash-dot-dot line has a diameter L2 of 200 mm Further, each of angle θ1 defined between line PQ3 and line PQ1, angle θ2 defined between line PQ1 and line PQ2, and angle θ3 defined between line PQ2 and line PQ3 is 120 degrees. In this way, each of locations at which the wafer W is supported by the support pins 25 is separated from the center of the wafer W by two-thirds of a radius of the wafer W, and as shown in FIG. 4, the respective support pins 25 are disposed to be placed at vertices of an equilateral triangle.

Here, the present disclosure may also be applied to a wafer W having a diameter of 450 mm (hereinafter, referred to as a 450 mm wafer W). When supporting the 450 mm wafer W, the support pins 25 are disposed to support the wafer W at locations separated from the center of the wafer W by two-thirds (⅔) of a radius of the wafer W, that is, by a distance of 150 mm from the center of the wafer W. In addition, as in the case of supporting a wafer W having a diameter of 300 mm (hereinafter, referred to as a 300 mm wafer W), the respective support pins 25 are disposed to be placed at vertices of an equilateral triangle on the bottom surface 22 of the recess.

In this regard, it should be noted that, because production tolerance of the apparatus, diameter tolerance of substrates, and the like is unavoidable, a misalignment of 1 mm of the support pins 25 from support points of a substrate falls within the scope of the present disclosure, wherein the support points are separated from the center of the substrate by two-thirds (⅔) of a radius of the corresponding substrate and are placed at vertices of an equilateral triangle on the bottom surface 22 of the recess 21. Specifically, for example, when supporting a 300 mm wafer W, although the support pins 25 are described as supporting the wafer W at locations separated from the center of the wafer W by a distance of 100 mm in the radial direction of the wafer W, the arrangement of the support pins 25 to support the wafer W at locations separated from the center of the wafer by a distance of 99 mm to 101 mm also falls within the scope of the present disclosure. Since a misalignment of 1 mm of the support pins 25 from support points not only in the radial direction of the wafer W but also in the circumferential direction of the wafer W falls within the scope of the present disclosure, the angles θ1 to θ3 are not limited to exactly 120 degrees.

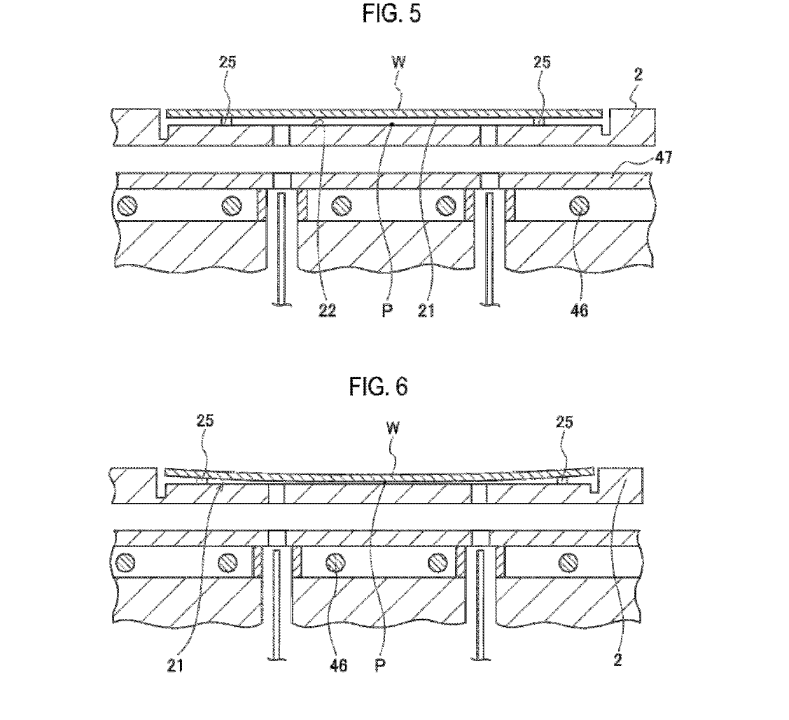

As shown in FIG. 5, the wafer W is supported in a state of being raised from the bottom surface 22 of the recess by these support pins 25, whereby a rate of heat transfer that heat is transferred from the bottom surface 22 to the wafer W is reduced. Specifically, upon delivery of the wafer W, the rotatable table 2 is heated by the heaters 46. If the support pins 25 are not provided, the wafer W is brought into direct contact with the bottom surface 22 of the recess 21. That is, since the entire or substantially the entire lower surface of the wafer W contacts the rotatable table 2, a contact area between the wafer W and the rotatable table 2 is relatively large. Accordingly, the rate of heat transfer from the rotatable table 2 to the wafer W is high. In addition, the wafer W loaded on the bottom surface 22 is affected by, for example, a temperature distribution created in the bottom surface 22, so that heat is rapidly transferred with a temperature difference being created between in-plane portions of the wafer W. As a result, when the temperature difference between the in-plane portions of the wafer W is not relieved, the temperature of the wafer W is rapidly increased, thereby causing bending of the wafer W, as described above in the background.

However, with the support pins 25 provided to the recess 21, a contact area between the lower surface of the wafer W and the rotatable table 2 is suppressed to a small area, which is the same as the sum of upper surface areas of the three support pins 25, thereby reducing the rate of heat transfer from the rotatable table 2 to the wafer W. Heat transferred from the support pins 25 to the wafer W diffuses on the surface of the wafer W. Since the rate of heat transfer from the rotatable table 2 to the wafer W is reduced, a sufficient quantity of heat diffuses on the surface of the wafer W to increase the temperature of the respective in-plane portions of the wafer W while relieving a temperature gradient between the in-plane portions of the wafer W. In this way, the wafer W can be heated while suppressing generation of the in-plane temperature gradient in the wafer W, thereby preventing the wafer W from bending or from suffering an increase in bending degree.

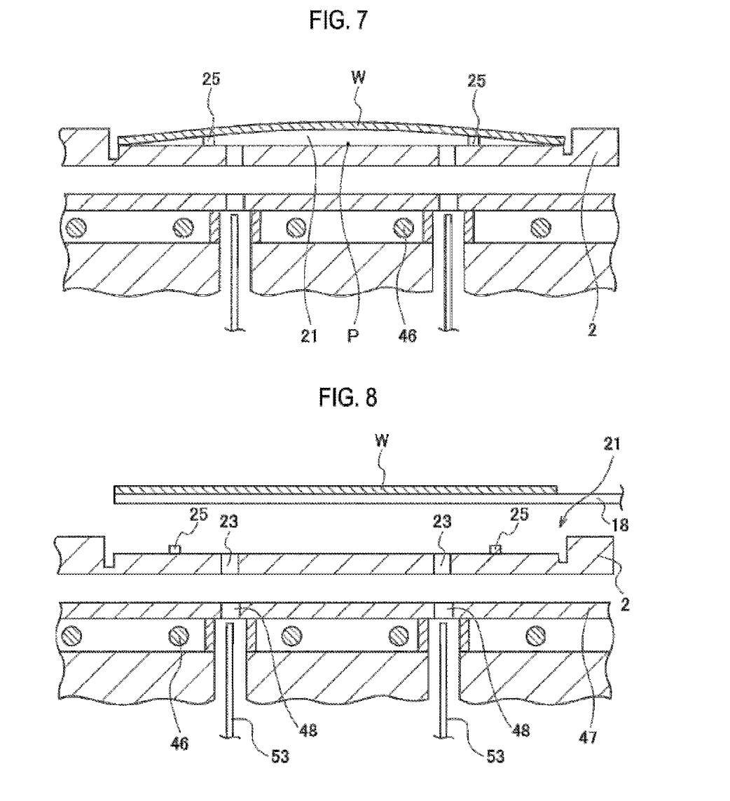

Here, with the arrangement of the support pins 25 at the locations as described above, bending of the wafer W due to the weight of the wafer W is suppressed while the wafer W is supported on the support pins 25, whereby the wafer W can be loaded in a flat shape or in a substantially flat shape on the bottom surface 22. For convenience of description, FIGS. 6 and 7 show comparative examples. In FIG. 6, each of the support pins 25 is separated from the center P of the recess 21 further than the support pins 25 shown in FIGS. 4 and 5 while supporting the wafer W. In this case, the wafer W is supported in a bent state that the center of the wafer W is placed below the periphery of the wafer W due to the weight of the wafer W. In FIG. 7, each of the support pins 25 is disposed closer to the center P of the recess than the support pins 25 shown in FIG. 4 while supporting the wafer W. In this case, the wafer W is supported in a bent state that the center of the wafer W is placed above the periphery of the wafer W due to the weight of the wafer W.

With the arrangement of the support pins 25 as shown in FIGS. 6 and 7, the wafer W has a high degree of bending, thereby causing low uniformity in distance between each in-plane portion of the wafer W and the bottom surface 22. As a result, the respective in-plane portions of the wafer W receive uneven quantities of radiant heat from the bottom surface 22, so that a temperature difference is likely to occur on the surface of the wafer W. Further, when the wafer W is supported to have a higher degree of bending than the wafers W shown in FIGS. 6 and 7 such that a portion of the wafer W contacts the bottom surface 22 and is subjected to a rapid increase in temperature due to conduction of heat, thereby further increasing the temperature difference in the in-plane portions of the wafer W.

On the contrary, the arrangement of the support pins 25 as shown in FIGS. 4 and 5 allows the wafer W to be loaded on the support pins 25 while suppressing bending of the wafer more than the arrangement of the support pins 25 as shown in FIGS. 6 and 7, whereby the in-plane portions of the wafer W can receive uniform radiant heat from the bottom surface 22 and the wafer W can be prevented from contacting the bottom surface 22. Accordingly, it is possible to prevent generation of the temperature difference between the respective in-plane portions of the wafer W, thereby preventing the wafer W from bending or from suffering an increase in bending degree. Further, when the wafer W is supported by the support pins while suppressing bending of the wafer as shown in FIGS. 4 and 5, a bulging height of the wafer W in an upper direction of the recess 21 can be suppressed even in the case where the wafer is bent, and this feature will be described below.

The height H1 of the support pins 25 (see FIG. 1) is not limited to the aforementioned value, and may be set in the range of, for example, 0.01 mm to 1 mm in order to allow the wafer W to be efficiently heated by radiant heat from the bottom surface 22 while preventing the wafer from bulging above the recess 21. Further, the diameter L1 of the support pins 25 (see FIG. 4) is not limited to the aforementioned value, and may be set in any range to provide sufficient friction to the wafer W so as to prevent the wafer W from being separated from the recess 21 during rotation of the rotatable table 2, while efficiently suppressing heat transfer to the wafer W. Specifically, the support pins 25 may have a diameter of, for example, 5 mm to 20 mm.

Referring again to FIGS. 2 and 3, other components of the film formation apparatus 1 will be described hereinafter. Reference numeral 55 indicates a cleaning gas nozzle. The cleaning gas nozzle 55 ejects a fluorine-based cleaning gas such as ClF₃ (chlorine trifluoride) from a proximal end thereof to an upper space of the rotatable table 2. The fluorine-based cleaning gas contains fluorine or a fluorine compound as a main component of the gas. The ejected cleaning gas is supplied from the periphery of the rotatable table 2 towards the center thereof and removes a silicon oxide layer from the rotatable table 2.

As shown in FIG. 1, the film formation apparatus 1 is provided with a controller 10, which includes a computer for controlling overall operation of the entirety of the apparatus. As described below, the controller 10 stores programs for implementation of delivery of wafers W between the wafer transport mechanism 18 and the rotatable table 2, film formation and cleaning with respect to the wafers W. The programs are configured to transmit control signals to the respective parts of the film formation apparatus 1 to control operation of the corresponding parts.

Specifically, the programs are configured to control: supplying/shutting off respective gases from gas sources (not shown) to the respective gas nozzles 31 to 34, the cleaning gas nozzle 55, the central region C, and the like; a rotational speed of the rotatable table 2 rotated by the rotation driving mechanism 15; exhaust amounts through the respective exhaust ports 37, 37 by the exhaust adjustment mechanism 39; lifting of the lift pins 53 by the lift drive mechanism 54; and supply of power to the heaters 46, and the like. The programs are composed of step groups to implement processes described below through control of such operation. The programs are installed in the controller 10 through a storage medium such as a hard disk, a compact disk, a magneto-optical disk, a memory card, a flexible disk, and the like.

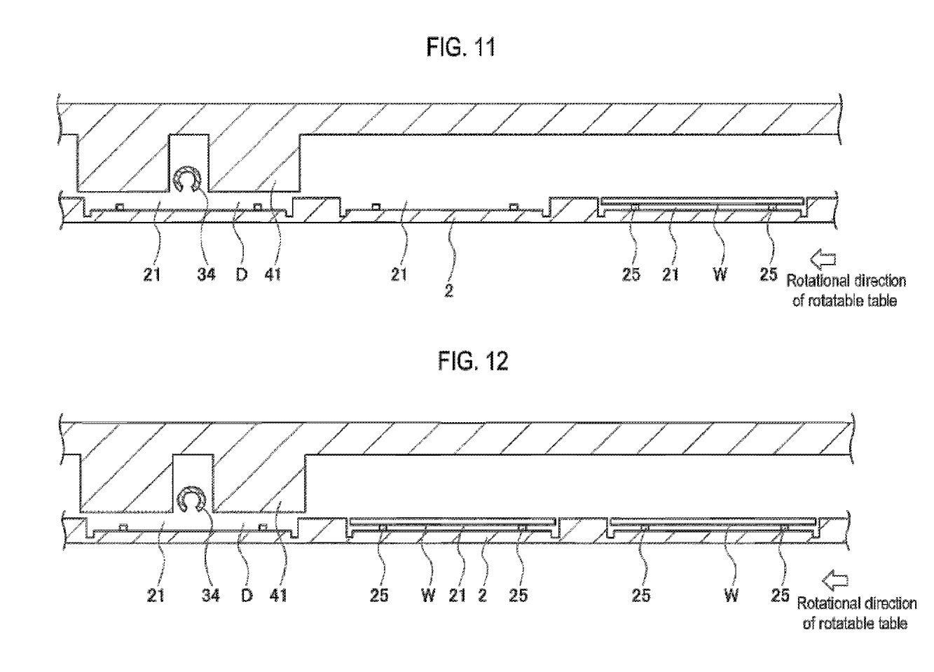

Next, delivery of a wafer W between the rotatable table 2 and the wafer transport mechanism 18 will be described with reference to FIGS. 8 to 13. FIGS. 8 to 10 are longitudinal sectional-views of the rotatable table 2 in the radial direction thereof, and FIGS. 11 to 13 are longitudinal sectional views of the vacuum container 11 in the circumferential direction of the rotatable table 2. First, the vacuum container 11 is exhausted through the exhaust ports 37, 37 to create a vacuum atmosphere having a predetermined pressure. From the central region C and the isolation gas nozzles 32, 34, a very small quantity of N₂ gas is supplied to prevent the atmosphere of the vacuum container 11 from being introduced into the central region C and the isolation gas nozzles 32, 34.

Under the vacuum atmosphere, the rotatable table 2 is heated to 600 degrees C. or more, for example, 720 degrees C., by the heaters 46, and one recess 21 of the rotatable table 2 is placed such that the through-holes 23 overlap the through-holes 48 of the plate 47 under the rotatable table 2. A location of the corresponding recess 21 will be referred to as a location facing the transport opening 16. In this state, the gate valve 17 is open, and the wafer transport mechanism 18 holding a wafer W (a first wafer W) enters the vacuum container 11 through the transport opening 16 and is placed above the recess 21 (FIG. 8).

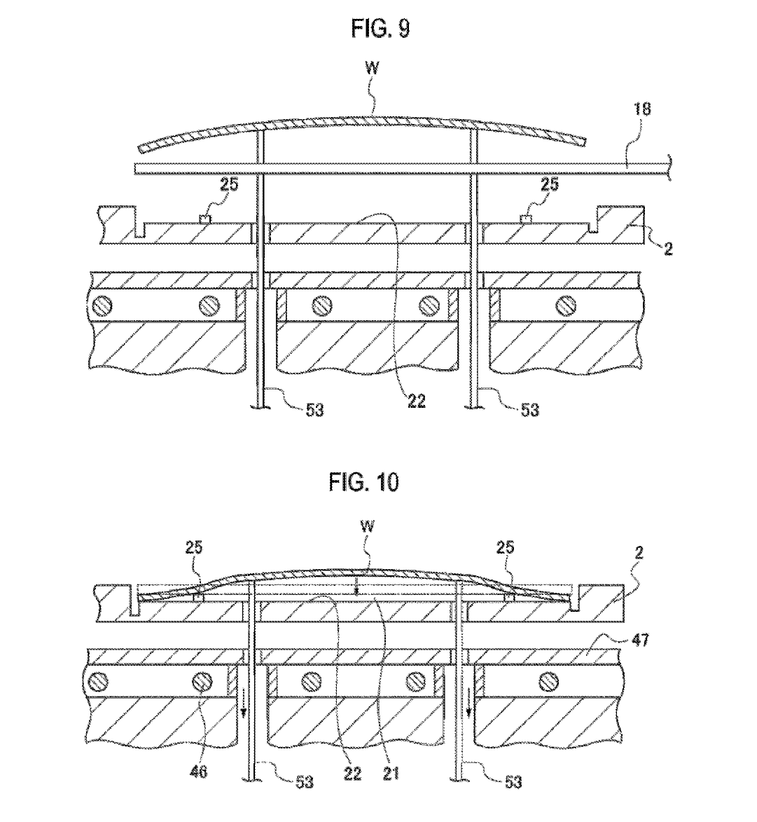

When the lift pins 53 are raised and push a lower surface of the wafer W from the wafer transport mechanism 18 (FIG. 9), the wafer transport mechanism 18 is withdrawn from the vacuum container 11 in order to receive another wafer W (a second wafer W) to be delivered into the vacuum container 11. As the lift pins 53 are lowered, the wafer W is lowered towards the bottom surface 22 of the recess 21 while being supported by the lift pins 53 in a state of being bent by the weight of the wafer W, and then sit on the support pins 25 (FIG. 10) such that a central point of the wafer W coincides with the center P of the recess 21, as described in FIG. 4. The lift pins 53 are further lowered from the lower surface of the wafer W and stopped below the plate 47. The support pins 25 suppress bending of the wafer W due to the weight thereof, as described in FIG. 5, so that the wafer W is supported in a flat shape. FIG. 11 also shows the wafer W supported by the support pins 25.

The wafer W supported by the support pins 25 is heated by conduction of heat from the support pins 25 and radiant heat from the bottom surface 22 of the recess 21. As described above, since a contact area between the support pins 25 and the wafer W is small, a heat flow rate to the wafer W is suppressed, thereby suppressing generation of an in-plane temperature gradient in the wafer W, that is, a temperature difference. As a result, the temperature of the wafer W is raised while suppressing bending of the wafer W.

After the lift pins 53 are stopped, the rotatable table 2 is rotated such that a recess 21 adjacent the recess 21 receiving the first wafer W is moved towards the location facing the transport opening 16. During rotation of the rotatable table 2, the first wafer W is suppressed from bending and is thus received in the recess 21. That is, the wafer W is suppressed from bulging above the recess 21. Accordingly, it is difficult for the first wafer W to receive pressure from an exhaust flow created on an upper surface of the rotatable table 2. As a result, even upon generation of centrifugal force by rotation of the rotatable table 2, the force exerted on the first wafer W is minimized, thereby preventing misalignment of the first wafer W in the recess 21 or separation of the first wafer W from the recess 21.

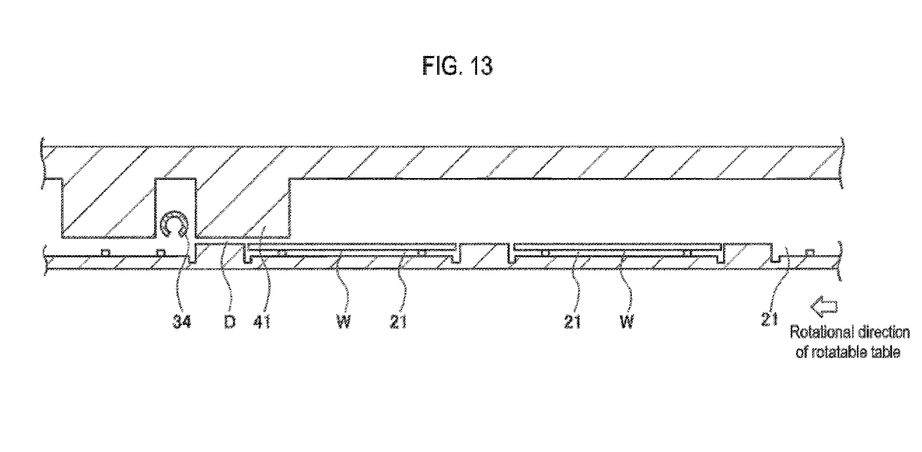

When the adjacent recess 21 is placed at the location facing the transport opening 16, the rotation of the rotatable table 2 is stopped, and the second wafer W is delivered to and heated on the recess 21 in the same way as the first wafer W (FIG. 12). Next, in order to receive a third wafer W, the rotatable table 2 is rotated and a recess 21 adjacent the recess 21 receiving the second wafer W is moved towards the location facing the transport opening 16. During this rotation, the bending is suppressed, thereby preventing misalignment of the first and seconds wafers W or separation of the first and second wafers W from the recess 21. Further, during this rotation, the heated first wafer W passes under the isolation gas nozzle 34 and the bump feature 41 that defines the isolation regions D (FIG. 13). Since the first wafer W does not bulge above the recess 21 due to suppression of bending as described above, the first wafer W can move without interference with the bump feature 41 and the isolation gas nozzle 34.

Like the first and second wafers W, the third wafer W is delivered to the recess 21 and heated therein. Then, through repetition of rotating and stopping the rotatable table 2, fourth and fifth wafers W are delivered to the recess 21. Further, in this delivering operation, since the wafers W delivered to the corresponding recesses 21 during rotation of the rotatable table 2 is suppressed from bending, the wafers are moved and heated without interference with the respective bump features 41, the isolation gas nozzles 32, 34 and the first and second reaction gas nozzles 31, 33. Further, misalignment of the wafers in the recesses 21 or separation of the wafers W therefrom is also avoided.

After delivery of a fifth wafer W to the recess 21, the gate valve 17 is closed. Then, the rotatable table 2 that has been stopped is rotated and all of the wafers W are heated to the temperature of the rotatable table 2, for example, 720 degrees C. When a predetermined period of time elapses after receiving the fifth wafer W, a supply amount of N₂ gas to the isolation gas nozzles 32, 34 and the central region C is increased, so that the amount of N₂ gas ejected through these parts is increased. Further, together with increase in ejection amount of the N₂ gas, the reaction gases are supplied from the first reaction gas nozzle 31 and the second reaction gas nozzle 33 to start film formation processing.

The wafers W alternatively pass through the first processing region P1 below the first reaction gas nozzle 31 and the second processing region P2 below the second reaction gas nozzle 33, such that BTBAS gas and O₃ gas are sequentially adsorbed to the wafers W to form one or a plurality of silicon oxide molecular layers through oxidation of BTBAS molecules. In this way, the silicon oxide molecular layers are sequentially stacked to form a silicon oxide layer having a predetermined thickness. Further, since the silicon oxide layer is in a heated state to a temperature of 600 degrees C. or more, annealing of the silicon oxide layer occurs, thereby preventing deformation of molecular arrangement of silicon oxide.

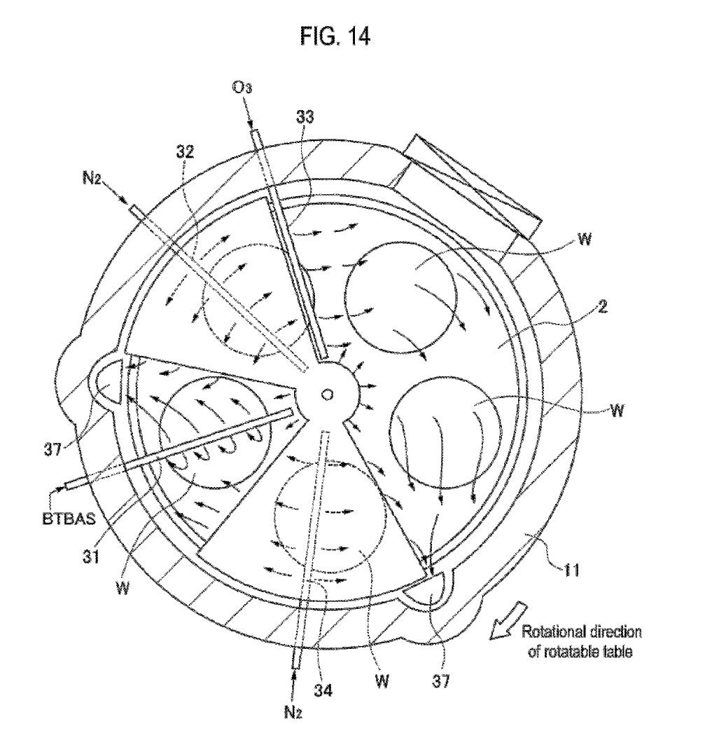

In FIG. 14, the gas flow within the vacuum container 11 is indicated by arrows. The N₂ gas supplied to the isolation regions D through the isolation gas nozzles 32, 34 spreads in the circumferential direction of the isolation regions D, thereby preventing the BTBAS gas and the O₃ gas from being mixed with each other above the rotatable table 2. In addition, the N₂ gas supplied to the central region C flows outside the rotatable table 2 in the radial direction of the rotatable table 2, thereby preventing the BTBAS gas and the O₃ gas from being mixed with each other in the central region C. Further, during this film formation processing, the N₂ gas is also supplied to a heater receiving space 45 and a rear side of the rotatable table 2 through the gas supply pipes 44, 49 (see FIG. 1) to purge the reaction gases.

When the silicon oxide layer is formed to have a predetermined thickness through a predetermined number of rotations of the rotatable table 2, a flow rate of each gas supplied through the respective gas nozzles 31 to 34 and the flow rate of the N₂ gas supplied to the central region C are reduced. Then, the rotation of the rotatable table 2 is stopped and the gate valve 17 is opened. After the gate valve 17 is opened, the wafers W are sequentially provided to the wafer transport mechanism 18 through intermittent rotation of the rotatable table 2 and a lifting operation of the lift pins 53, and are delivered outside the vacuum container 11. After all of the wafers W are delivered, the gate valve 17 is closed.

Thereafter, the rotatable table 2 is continuously rotated and a cleaning gas is supplied towards the upper surface of the rotatable table 2 through the cleaning gas nozzle 55 to start a cleaning process. The cleaning gas supplied to the rotatable table 2 decomposes the silicon oxide layer formed on the rotatable table 2 and is then absorbed together with decomposed materials into the exhaust ports 37. Then, after the rotatable table 2 is rotated a predetermined number of times, the rotation of the rotatable table 2 is stopped while stopping supply of the cleaning gas, thereby finishing the cleaning process. Thereafter, new wafers W are delivered into the vacuum container 11 to perform film formation.

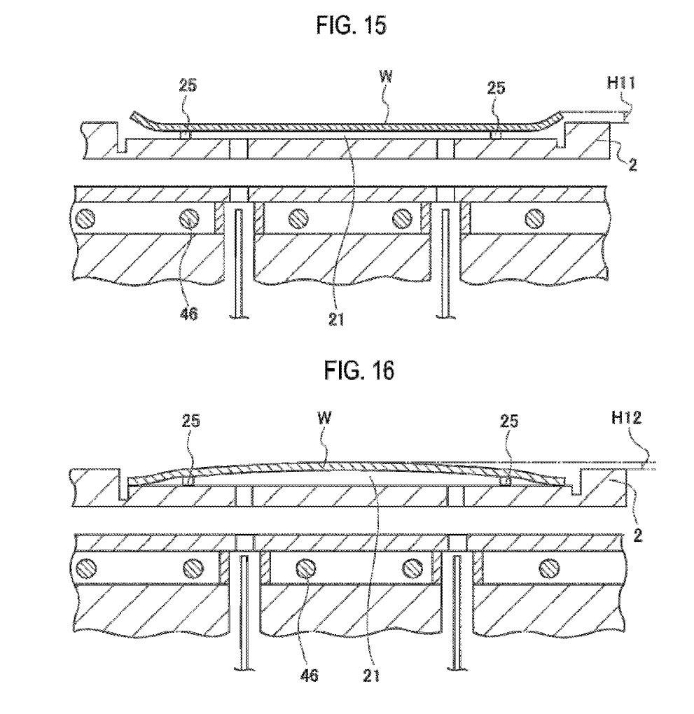

Here, although the wafers W have been illustrated as not suffering from bending when put on the support pins 25 in the drawings, the wafers sometimes undergo a slight degree of bending. FIG. 15 shows one example of a wafer W, which is bent such that the periphery of the wafer W has a higher height than the center of the wafer W when the wafer W is put on the support pins 25. Even in this case, the bending of the wafer W is gradually relieved by relieving an in-plane temperature gradient of the wafer W through heat transfer on the surface of the wafer W during an increase in temperature of the wafer W, whereby the wafer W is returned to a flat shape, as shown in FIG. 5.

FIG. 16 shows one example of a wafer W, which is bent such that the center of the wafer W has a higher height than the periphery of the wafer W unlike FIG. 15, when the wafer W is put on the support pins 25. Even if the wafer is bent, the wafer W is returned to a flat shape, as shown in FIG. 5, when the temperature gradient in the wafer W is relieved.

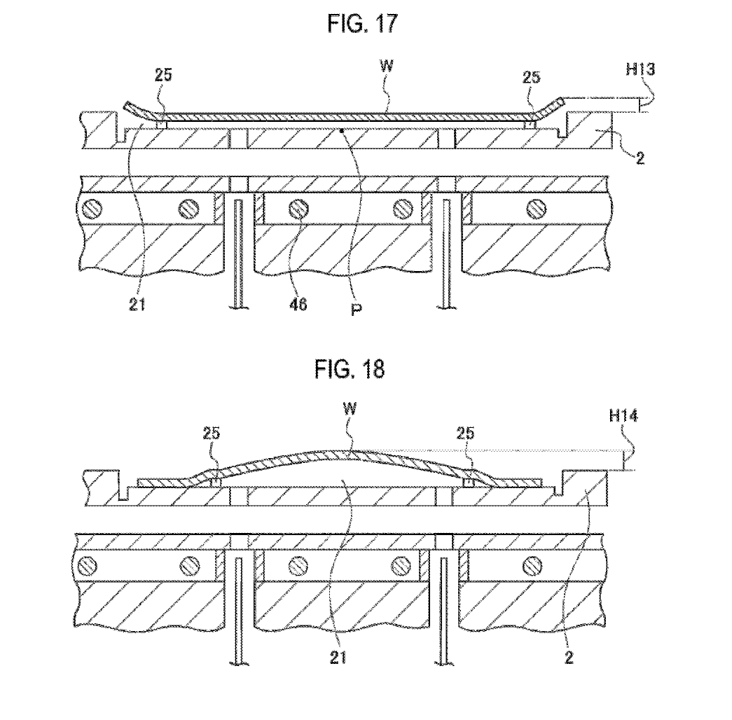

On the other hand, FIG. 17 shows one comparative example of the wafer W supported by the support pins 25 of FIG. 6 and bent like the wafer W of FIG. 15. As described above, in FIG. 6, since the support pins 25 are separated a relatively large distance from the center P of the recess 21, the wafer W supported on the support pins 25 is bent such that the periphery of the wafer W has a higher height than the center of the wafer W. Thus, even in the case where the wafer W has the same degree of bending as that of the wafer W shown in FIG. 15, a height from the surface of the rotatable table 2 to an upper end of the wafer W is further increased. That is, heights H11 and H13 from the surface of the rotatable table 2 to an upper end of the wafer W shown in FIGS. 15 and 17 have a relationship of H11<H13.

In addition, FIG. 18 shows one comparative example of the wafer W supported by the support pins 25 of FIG. 7 and bent like the wafer W of FIG. 16. As described above, in FIG. 7, since the support pins 25 are separated a relatively small distance from the center P of the recess 21, the wafer W is supported and bent such that the center of the wafer W has a higher height. Thus, even in the case where the wafer W has the same degree of bending as that of the wafer W shown in FIG. 16, the height from the surface of the rotatable table 2 to the upper end of the wafer W is further increased, as shown in FIG. 18. That is, the heights H12 and H14 from the surface of the rotatable table 2 to an upper end of the wafer W shown in FIGS. 16 and 18 have a relationship of H12<H14.

With the arrangement of the support pins 25 as described in FIG. 4, it is possible to reduce a bulging amount of the wafer W from an upper end of a sidewall of the recess 21 even when the wafer W is bent. When the bulging amount of the wafer is suppressed even in the case where the wafer W is bent, it is difficult for gas flow to affect the wafer W during rotation of the rotatable table 2, thereby preventing misalignment of the wafer W and interference of the wafer W with the bump features 41 of the isolation regions D or the gas nozzles 31 to 34. That is, even when the wafer W is in a bent state, the rotation of the rotatable table 2 can be performed to deliver the wafer W or to perform film formation processing.

In this film formation apparatus 1, the wafer W is supported by the support pins 25, which are installed above the bottom surface 22 of the recess 21 in the rotatable table 2, and is heated while suppressing bending of the wafer W due to the weight thereof. As a result, the rate of heat transfer from the bottom surface 22 to the wafer W is suppressed and the deviation in radiant heat from the bottom surface 22 to each of the in-plane portions of the wafer W is suppressed, thereby suppressing bending of the wafer W. In addition, since the wafer W is supported in a state that bending of the wafer W is suppressed, the wafer W is suppressed from bulging above the recess 21. Accordingly, after delivery of the wafer W to one recess 21, the rotatable table 2 can be rotated at a rapid rate to deliver another wafer W to the next recess 21, whereby the wafers W can be rapidly loaded on the respective recesses 21 in the film formation apparatus 1. In addition, while the rotatable table 2 is rotated, it is possible to wait until the temperature of the fifth wafer W, which is delivered to the rotatable table 2 last, reaches a preset temperature. After the temperature of the wafer W reaches a preset temperature, it is possible to perform film formation processing by rapidly supplying the reaction gases to the respective rotating wafers W. That is, it is possible to accelerate the timing of the start of film formation processing through ejection of the reaction gases, as compared with starting rotation of the rotatable table 2 after the temperature of the fifth wafer W reaches a preset temperature and bending of the fifth wafer W is relieved. As such, since it is possible to reduce the time for loading the wafers W and to accelerate the timing of the start of film formation processing, the film formation apparatus 1 has improved throughput. Further, since the contact area between the lower surface (rear surface) of the wafer W and the support pins 25 is relatively small, friction of the lower surface of the wafer W is suppressed, thereby reducing generation of particles.

In order to secure prevention of separation of the wafer W by adjusting the in-plane temperature distribution of the wafer W or increasing friction between the lower surface of the wafer W and the recess 21, a support pin (for convenience, an assistant support pin) having the same structure as that of the support pins 25 may be further provided to the bottom surface 22 of the recess 21. Specifically, the wafer W may be supported above the bottom surface 22 by three support pins 25 and the assistant support pin. A single assistant support pin or a plurality of assistant support pins may be provided. In addition, the support pins 25 are not limited to a cylindrical shape, and may have any shape capable of reducing the rate of heat transfer to the wafer W while suppressing bending of the wafer W, for example, a prism shape.

### Second Embodiment

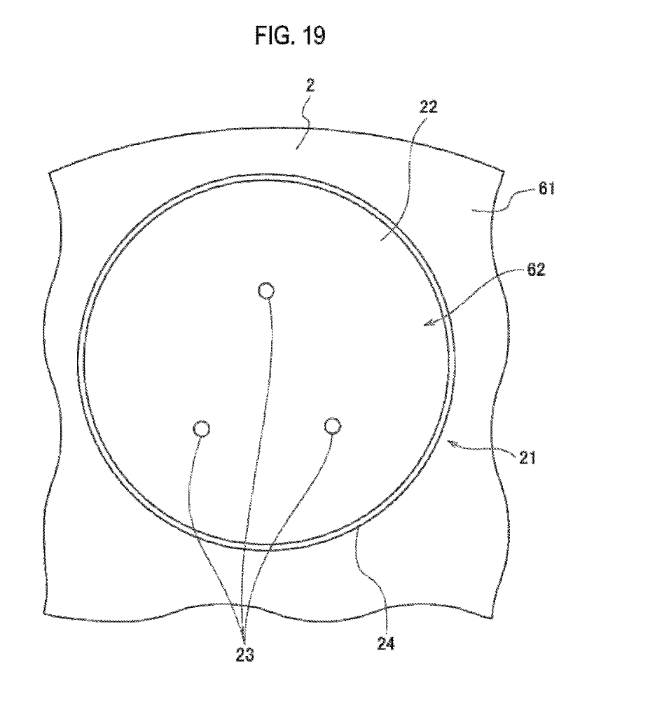

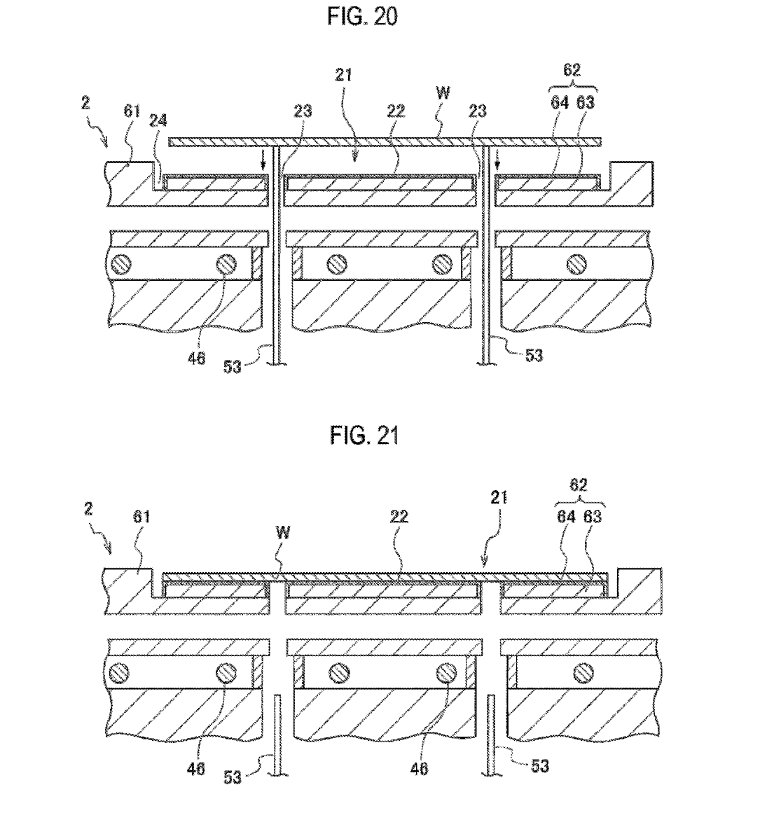

Next, a second embodiment of the present disclosure will be described. The second embodiment has different features from that of the first embodiment in terms of the rotatable table 2. According to the second embodiment, the rotatable table 2 includes a table body 61 and a bottom surface forming portion 62. FIGS. 19 and 20 show a plan view and a longitudinal sectional-view of the rotatable table 2 according to the second embodiment, respectively. The bottom surface forming portion 62 has a flat circular shape and is placed on a bottom surface of a recess formed on an upper surface of the table body 61 to constitute a recess 21 which defines a wafer loading region. That is, an upper surface of the bottom surface forming portion 62 forms the bottom surface 22 of the recess 21 and an outer periphery of the bottom surface forming portion 62 forms a groove 24 of the recess 21.

The table body 61 is formed of quartz. The bottom surface forming portion 62 is composed of a body section 63 mainly formed of silicon carbide (SiC) and a coating 64 of yttrium oxide (Y₂O₃) covering a surface of the body section 63. The coating 64 is formed to prevent the body section 63 from being etched by a cleaning gas upon cleaning. Since the bottom surface forming portion 62 is mainly formed of SiC, the bottom surface 22 of the recess 21 has higher thermal conductivity than the table body 61 and thus suppresses generation of a temperature gradient therein.

Like the first embodiment, in the second embodiment, a wafer W is delivered toward the recess 21 by lift pins 53, as shown in FIG. 20, and is loaded such that the entire lower surface of the wafer W directly contacts the bottom surface 22 of the recess 21, as shown in FIG. 21. In this case, although the rate of heat transfer to the wafer W is higher than that of the first embodiment, the bottom surface 22 has a lower temperature gradient, thereby allowing a temperature increase in each in-plane portion of the wafer W while preventing an increase in temperature gradient in the respective in-plane portions of the wafer W. That is, the wafer W is heated while maintaining a high uniformity of the heat flow rate in the respective in-plane portions of the wafer W. As the wafer W is heated in this way, there is an effect of suppressing bending of the wafer W as in the first embodiment. Accordingly, according to this embodiment, since the wafer W is prevented from bulging above the recess 21, it is possible to achieve rapid delivery of the wafer to the recess 21 while accelerating the timing of the start of film formation processing, as in the first embodiment.

Materials for the bottom surface forming portion 62 are not limited to the aforementioned materials so long as the materials ensure that thermal conductivity of the bottom surface 22 is higher than the table body 61 that is formed of quartz and constitutes the outside of the bottom surface 22. For example, the body section 63 may be mainly formed of carbon instead of SiC and may be covered by the coating 64. Alternatively, the body section 63 may be mainly formed of aluminum nitride AlN. Although the cleaning gas contains fluorine or a fluorine compound as mentioned above, it is difficult for the cleaning gas to corrode AlN. Thus, when the body section 63 is formed of MN, the coating 64 may be omitted.

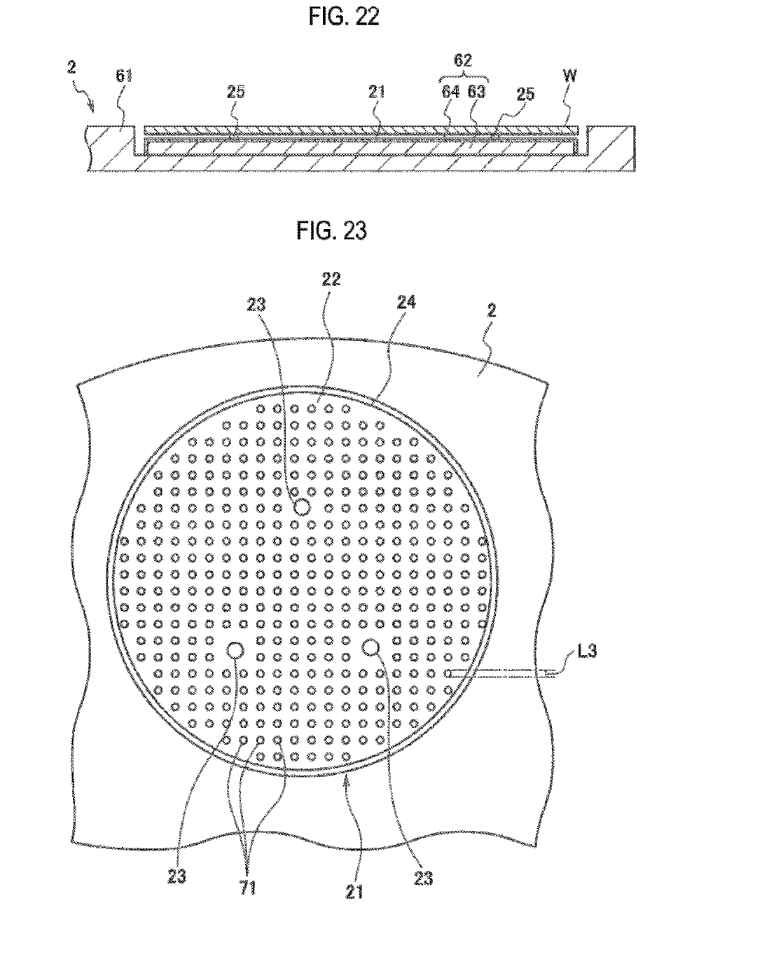

The second embodiment may be combined with the first embodiment. That is, as shown in FIG. 22, the support pins 25 may be placed on the bottom surface forming portion 62. Even in this case, occurrence of the temperature gradient is suppressed in the bottom surface 22 of the recess 21, thereby suppressing deviation in quantity of radiant heat supplied from each portion of the bottom surface 22 to the wafer W. Accordingly, since occurrence of the in-plane temperature gradient can be more securely suppressed in the wafer W, it is possible to suppress bending of the wafer W or increase the degree of bending of the wafer W.

### Third Embodiment

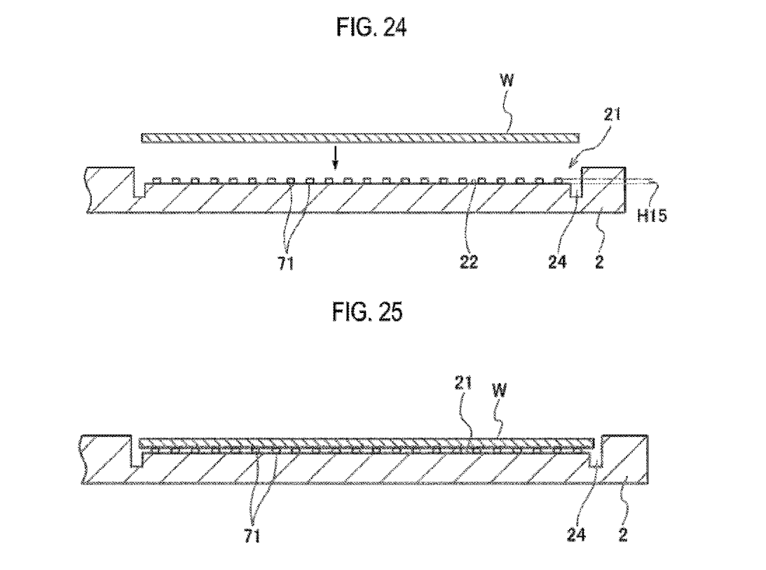

FIGS. 23 and 24 are a plan view and a longitudinal sectional-view of a recess 21 according to a third embodiment of the present disclosure, respectively. Compared to the first embodiment, in the third embodiment, a plurality of support pins 71 is disposed on a bottom surface 22 of the recess 21 instead of the support pins 25, and the support pins 71 are arranged in a matrix shape in a plan view. Each of the support pins 71 has a cylindrical shape and supports a wafer W on an upper surface thereof, like the support pins 25 according to the first embodiment. FIG. 25 shows a wafer W supported on the support pins 71. Like the support pins 25, the support pins 71 raise a lower surface of the wafer from the bottom surface 22 of the recess 21 by supporting the wafer W in this way, thereby reducing the rate of heat transfer to the wafer W.

In order to restrain the rate of heat transfer to the wafer W, the support pins 71 are disposed to have a contact area ratio of 8% to 12%, as calculated according to Equation: (total contact area between support pins 71 and wafer W/lower surface area of wafer W)×100 (unit: %). In FIG. 23, the support pins 71 have a diameter L3 of, for example, 5 mm. In FIG. 24, the support pins 71 have a height H15 of, for example, 0.01 mm to 1 mm. In the embodiment shown in FIG. 24, the support pins 71 have a height H15 of 0.05 mm. Like the height H1 of the support pins 25 according to the first embodiment, the height H15 of the support pins 71 is set to efficiently heat the wafer using radiant heat from the bottom surface 22 and to prevent the wafer W from bulging above the recess 21.

As in the first embodiment, the third embodiment can suppress bending of the wafer W delivered to the recess 21. Thus, as in the first embodiment, the third embodiment can allow rapid delivery of the wafer W to the recess 21 and can accelerate timing of the start of film formation processing to improve throughput of the film formation apparatus 1. Here, it should be understood that, among the plural support pins 71, three support pins 71 may be disposed at the same locations as or at different locations than those of the support pins 25 shown in FIG. 4. When three support pins 71 are disposed at the same locations as those of the support pins 25 of FIG. 4, the wafer W can be more securely prevented from bulging above the recess 21 even in the event where bending of the wafer W occurs, as in the first embodiment.

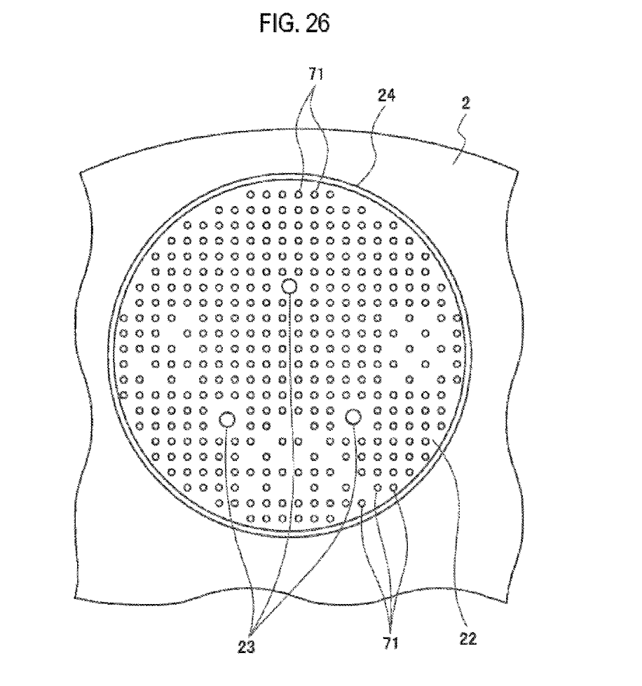

FIG. 26 is a plan view of modification of the third embodiment, in which the number of support pins 71 is less than that of the support pins shown in FIG. 23. When there is generation of particles within the bottom surface 22 after delivery of the wafer W to the recess 21, with the support pins 71 disposed as shown in FIG. 23, it is regarded that there is friction between the wafer W and the support pins 71 due to bending of the wafer W, and thus it is effective that the support pins 71 around portions generating the particles are subjected to thinning. FIG. 26 shows one example of the support pins 71 subjected to thinning. In this way, the support pins 71 may be arranged in any layout. Like the support pins 25 of the first embodiment, the support pins 71 may have any shape including a cylindrical shape, without being limited thereto. The third embodiment may also be combined with the second embodiment such that the lower surface of the recess 21 is constituted by the bottom surface forming portion 62.

The present disclosure may be applied not only to the film formation apparatus, but also to other apparatuses, for example, an apparatus for modifying or etching a layer of a wafer W by using plasma created from a process gas. In addition, it should be understood that the film formation apparatus according to the present disclosure is not limited to a silicon oxide layer as a target film. For example, the film formation apparatus according to the present disclosure may also be applied to formation of a silicon nitride layer or an aluminum nitride layer through ALD.

### Modification of First Embodiment

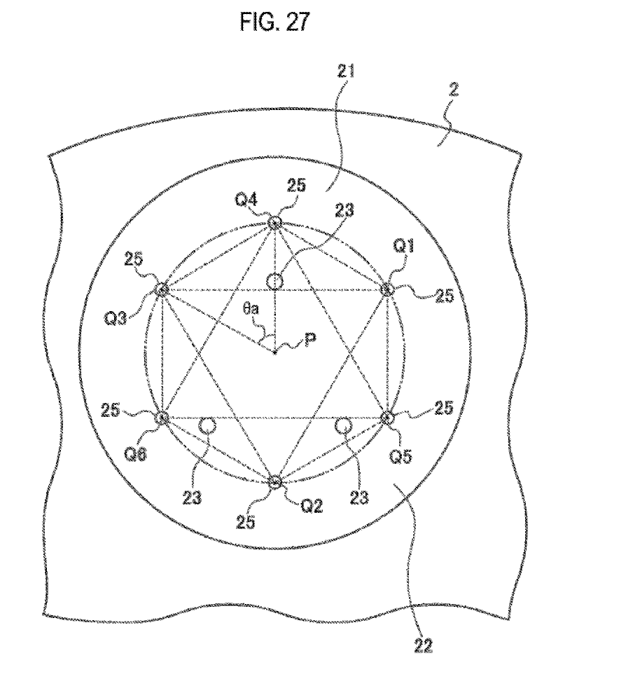

Next, modifications of the recess 21 according to the first embodiment will be described. Unlike the first embodiment shown in FIG. 4, in a first modification shown in FIG. 27, six support pins 25 are provided to the recess 21. In FIG. 27 and other drawings illustrating modifications described hereinafter, a dotted line and a dash-dot-dot line are imaginary lines for clearly depicting a positional relationship between the respective support pins 25. In addition, although the groove 24 is not shown on the bottom surface 22 of the recess 21 in each of the modifications including the first modification, the groove 24 may be formed or omitted, as in the first embodiment.

Assume three support pins 25 belong to a first group among the six support pins 25, the support pins 25 of the first group are disposed at the same locations as those of the support pins described in FIG. 4, and central points on upper surfaces of the support pins 25 are indicated by Q1 to Q3, respectively, as in the first embodiment shown in FIG. 4. Assume the other three support pins 25 belong to a second group, central points on upper surfaces of the support pins 25 of the second group are indicated by Q4 to Q6, respectively. Like points Q1 to Q3, points Q4 to Q6 are placed on a circumference of a circle having a center at point P and points Q4 to Q6 are placed at vertices of an equilateral triangle. In addition, when viewing the bottom surface 22 of the recess 21 from point P in the circumferential direction, vertices of one triangle respectively placed at points Q4 to Q6 and vertices of another triangle respectively placed at points Q1 to Q3 are alternately disposed. Points Q adjacent in the circumferential direction are separated from each other by an angle of θa=60 degrees at reference point P. That is, points Q1 to Q6 define a regular hexagon.

In this way, each of locations at which the wafer W is supported by the support pins 25 is separated from the center of the wafer W by two-thirds of a radius of the wafer W, and corresponds to each of the vertices of a regular hexagon having the center of mass at the center of the wafer W. In this first modification, the support pins 25 having the positional relationship as described in the first embodiment of FIG. 4 are distributed into two groups on the bottom surface 22 and more securely suppress bending of the wafer W to support the wafer W in a horizontal state, thereby more securely preventing the wafer W from contacting the bottom surface 22. With this structure, the support pins can suppress bending of the wafer W by improving uniformity in temperature distribution in the wafer W. Like the support pins 25 of the first embodiment, in the first modification, even if the above location deviate by 1 mm from the supporting locations at which the wafer W is supported, it also falls within the scope of the present disclosure. In other words, embodiments in which the support pins 25 are not disposed precisely at vertices of a regular hexagon also fall within the scope of the present disclosure. Herein, unless otherwise specified, such tolerance can be applied to other support pins described hereinafter.

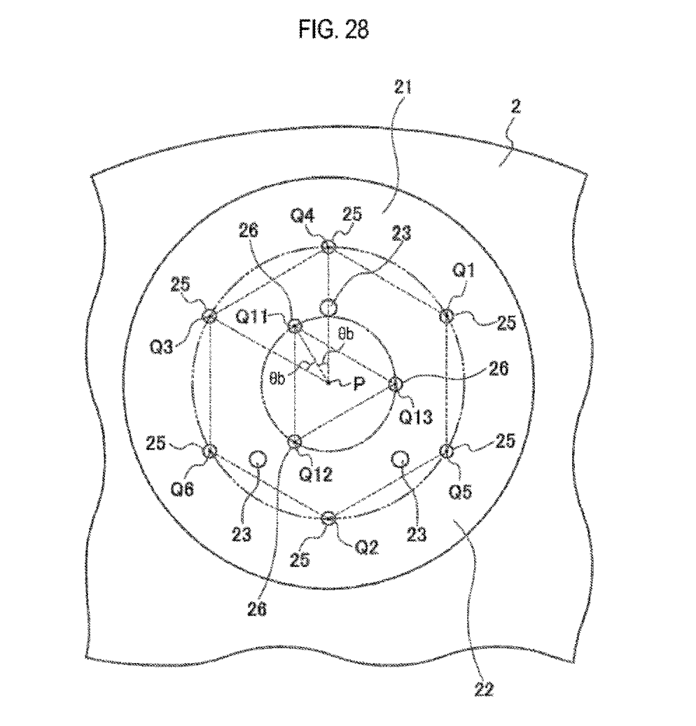

FIG. 28 shows a second modification of the recess 21 according to the first embodiment. In the second modification, in addition to the six support pins 25 described in the first modification, three support pins are disposed on the bottom surface of the recess 21 to be closer to the central point P of the bottom surface than the support pins 25. For convenience of description, these three support pins will be referred to as inner assistant support pins 26. The inner assistant support pins 26 have the same configuration as that of the support pins 25 except for the locations at which they are disposed.

Central points of upper surfaces of the inner assistant support pins (second assistant support pins) 26 are indicated by points Q11, Q12, Q13, respectively. Points Q11, Q12, Q13 are placed on a circumference of a circle having a center at point P and one-third (⅓) of the radius of the wafer W. In addition, points Q1, Q12, Q13 are placed at vertices of an equilateral triangle. The inner assistant support pins 26 are disposed to prevent interference with the through-holes 23. In this example, with regard to points Q of two adjacent support pins 25 in the circumferential direction, the line connecting point Q of the inner assistant support pin 26 and point P and the line connecting point Q of each of the two adjacent support pins 25 and point P form an angle of θb. Each of the inner assistant support pins 26 is placed such that θb is 30 degrees. According to the second modification, in addition to the support pins 25 of the two groups described in the first modification, the assistant support pins 26 are disposed to support the wafer W, whereby the wafer W can be supported while more securely suppressing bending of the wafer W.

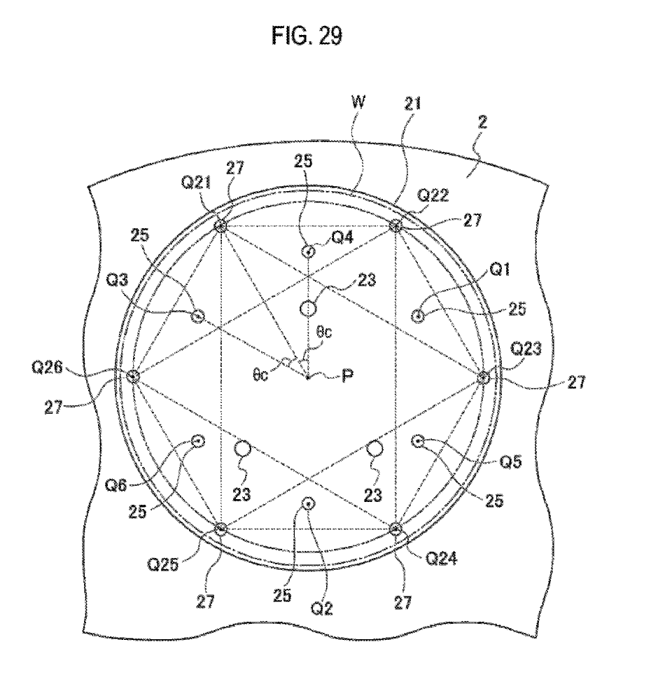

FIG. 29 shows a third modification of the recess 21. In the third modification, in addition to the six support pins 25 described in the first modification, six support pins are disposed on the bottom surface 22 of the recess 21 to be closer to the circumference of the bottom surface 22 of the recess 21 than the support pins 25. For convenience of description, these six support pins will be referred to as outer assistant support pins 27. The outer assistant support pins 27 have the same configuration as that of the support pins 25 except for the locations at which they are disposed.

Central points of upper surfaces of the outer assistant support pins (first assistant support pins) 27 are indicated by points Q21 to Q26. Points Q21 to Q26 are disposed such that the outer assistant support pins support the wafer W at locations separated a distance of 3 mm from a circumference end of the wafer W towards the center of the wafer. As used herein, the wafer W may refer to a 300 mm wafer W or a 450 mm wafer W. With this arrangement of points Q21 to Q26, the outer assistant support pins 27 support the wafer W so as not to contact the circumference end of the wafer W. In addition, like the support pins 25, points Q21 to 26 of the outer assistant support pins 27 are placed at vertices of a regular hexagon. The center of mass (center) of the regular hexagon having vertices at points Q21 to Q26 of the outer assistant support pins 27 coincides with the center of mass of the regular hexagon having vertices at points Q1 to Q6 of the support pins 25. The support pins 25 and the outer assistant support pins 27 are alternately arranged when viewed from point P in the circumferential direction. In addition, with respect to the support pin 25 and outer assistant support pin 27 adjacent to each other in the circumferential direction, an angle θc between a line extending from point Q of the adjacent support pin 25 to point P and a line extending from point Q of the outer assistant support pin 27 to point P is 30 degrees.

Like the second modification, in the third modification, the wafer W can be supported to more securely suppress its bending. Further, as shown in FIG. 17 and the like, in the case where the wafer W is bent to have low center and high periphery, if the support pins support an area around the center of the wafer W, there is a concern that the wafer W can further bulge above the recess 21. Accordingly, the outer assistant support pins 27 may be provided instead of the inner assistant support pins 26, in terms of suppression of the bulging height of the wafer W.

As such, the outer assistant support pins 27 are provided for the purpose of stably supporting the wafer W by supporting the wafer at locations further separated from point P than the support pins 25. The more the outer assistant support pins 27 are separated from the support pins 25 in the radial direction of the bottom surface 22 of the recess 21, the more the bending of the wafer W is suppressed at the periphery thereof. However, when the support pins contact the circumference end of the wafer W, particles are likely to be formed. Accordingly, as described above, the outer assistant support pins 27 are disposed so as not to contact the circumference end of the wafer W.

Namely, the present disclosure is not limited to such arrangement of the outer assistant support pins 27 disposed such that points Q21 to Q26 of the outer assistant support pins 27 support the wafer W at inner locations separated a distance of 3 mm from the circumference end of the wafer W. Specifically, the outer assistant support pins 27 may be arranged at intervals along a circumference of a circle having the center at point P to support the wafer W at locations farther outward than the locations of the wafer W supported by the support pin 25, while preventing the upper surfaces thereof from contacting the circumference end of the wafer W. Accordingly, for example, the outer assistant support pins 27 may be arranged such that points Q21 to Q26 of the outer assistant support pins 27 support the wafer W at inner locations separated a distance of 5 mm from the circumference end of the wafer W. Here, in order to achieve stable loading of the wafer W horizontally, it is desirable to support the wafer W at locations separated from the support pins 25. Further, in consideration of preventing the outer assistant support pins 27 from contacting the circumference end of the wafer W, in the above example, the outer assistant support pins 27 are disposed such that points Q21 to Q26 support the wafer W at the inner location separated a distance of 3 mm from the circumference end of the wafer W. Further, like the support pins 25, since the outer assistant support pins 27 may have an allowable tolerance, the present disclosure is not limited to arranging the outer assistant support pins 27 supporting the wafer W at locations defining an accurately regular hexagon.

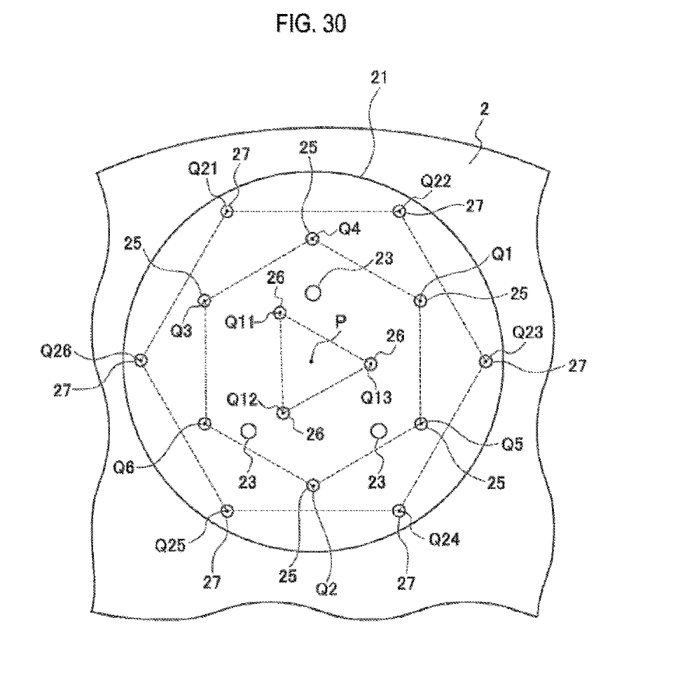

FIG. 30 shows a fourth modification of the recess 21 according to the first embodiment. In the fourth modification, in addition to the six support pins 25 described in the first modification, the inner assistant support pins 26 according to the second modification and the outer assistant support pins 27 according to the third modification may be provided. With this structure of the recess 21, it is possible to support the wafer W while suppressing bending of the wafer W. It should be understood that these respective modifications of the first embodiment may also be applied to the second and third embodiments.

According to the present disclosure in some embodiments, a substrate is supported by three support pins in a state of being raised from a bottom surface of a recess, in which arrangement of the support pins suppress deformation of the substrate due to the weight of the substrate. With this structure, a rate of heat transfer to the substrate is reduced and in-plane variation of a distance from the substrate to the bottom surface of the recess is suppressed. As a result, the substrate can be uniformly heated in plane. In addition, according to the present disclosure in other embodiments, a rotatable table includes a bottom surface forming portion that forms a bottom surface of a recess, on which a substrate will be loaded, and the bottom surface forming portion is mainly formed of a material having a higher thermal conductivity than a table body forming the outside of the bottom surface. With this structure, the bottom surface has a highly uniform in-plane temperature, whereby the substrate can be uniformly heated in plane. Further, according to the present disclosure in other embodiments, a contact area ratio of support pins with respect to an overall surface area of one surface of a substrate supported by the support pins is defined to reduce the rate of heat transfer from the bottom surface of the recess of the rotatable table to the substrate. With such features of the present disclosure, it is possible to suppress bulging of the substrate above the recess 21 by suppressing bending of the substrate due to generation of in-plane temperature difference in the substrate. Accordingly, after a substrate is delivered to one recess, a subsequent substrate can be rapidly delivered to the next recess, or the substrate can be rapidly subjected to certain processing, thereby improving throughput of the film formation apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus performing substrate processing by supplying a process gas to a circular substrate loaded on a rotatable table in a vacuum container while rotating the substrate, comprising:
a recess formed at one side of the rotatable table to receive the substrate;
a heater heating the rotatable table to heat the substrate to 600 degrees C. or more for processing; and
six support pins disposed on a bottom surface of the recess such that the support pins are respectively placed at vertices of a regular hexagon, support the substrate at locations separated by a distance of two-thirds (⅔) of a radius of the substrate from a center of the substrate, and support the substrate in a state of being raised from the bottom surface of the recess.

2. The substrate processing apparatus of claim 1, further comprising a plurality of assistant support pins placed on the bottom surface of the recess in order to support the substrate at locations which are farther outwards than the locations of the substrate supported by the support pins and are separated from a circumference end of the substrate towards the center of the substrate.

3. The substrate processing apparatus of claim 2, wherein the assistant support pins are respectively placed at six vertices of a regular hexagon on the bottom surface of the recess, and the center of mass of the regular hexagon defined by the assistant support pins coincides with the center of mass of the regular hexagon defined by the support pins.

4. The substrate processing apparatus of claim 1, further comprising a plurality of assistant support pins placed on the bottom surface of the recess in order to support the substrate at locations farther inward than the locations of the substrate supported by the support pins.

5. The substrate processing apparatus of claim 1, wherein the substrate is a silicon wafer having a diameter of 300 mm.

6. The substrate processing apparatus of claim 1, wherein the rotatable table comprises a bottom surface forming portion constituting the bottom surface of the recess, and a table body constituting the outside of the bottom surface, and
wherein the bottom surface forming portion is mainly formed of a material having higher thermal conductivity than that of the table body.

7. The substrate processing apparatus of claim 6, wherein the bottom surface forming portion is mainly formed of silicon carbide, carbon or aluminum nitride.

8. The substrate processing apparatus of claim 6, wherein the bottom surface forming portion has a surface coated with yttrium oxide.

9. A substrate processing apparatus performing substrate processing by supplying a process gas to a substrate loaded on a rotatable table in a vacuum container while rotating the substrate, comprising:
a recess formed at one side of the rotatable table to receive the substrate;
a heater heating the rotatable table to heat the substrate to 600 degrees C. or more for processing;
a bottom surface forming portion constituting a bottom surface of the recess on which the substrate is loaded in the rotatable table; and
a table body constituting the outside of the bottom surface in the rotatable table,
wherein the bottom surface forming portion is mainly formed of a material having higher thermal conductivity than the table body to suppress an in-plane temperature difference in the substrate by improving temperature uniformity within the bottom surface.

10. A substrate processing apparatus performing substrate processing by supplying a process gas to a circular substrate loaded on a rotatable table in a vacuum container while rotating the substrate, comprising:
a recess formed at one side of the rotatable table to receive the substrate;
a heater heating the rotatable table to heat the substrate to 600 degrees C. or more for processing; and
a plurality of support pins disposed on a bottom surface of the recess to support the substrate in a state of being raised from the bottom surface of the recess,
wherein a contact area ratio of the support pins with respect to an overall surface area of one surface of the substrate supported by the support pins ranges from 8% to 12% to reduce a rate of heat transfer from the bottom surface of the recess to the substrate.

11. The substrate processing apparatus of claim 10, wherein the support pins have a height of 0.01 mm to 1 mm
